(19) United States
(12) Patent Application Publication
(10) Pub. No.: US 2025/0379179 A1
(43) Pub. Date: Dec. 11, 2025

(54) SEMICONDUCTOR PACKAGE

(71) Applicant: SAMSUNG ELECTRONICS CO., LTD., Suwon-si (KR)

(72) Inventors: Junbae Kim, Suwon-si (KR); Yangki Kim, Suwon-si (KR); Taeho Kim, Suwon-si (KR); Changsoo Yoon, Suwon-si (KR)

(21) Appl. No.: 19/018,389

(22) Filed: Jan. 13, 2025

(30) Foreign Application Priority Data
Jun. 7, 2024 (KR) 10-2024-0074197

(51) Int. Cl. H01L 23/00; H01L 25/16; H10B 80/00; H10D 80/30

(52) U.S. Cl. CPC H01L 24/49; H01L 24/06; H01L 24/48; H01L 25/16; H10B 80/00; H10D 80/30; H01L 24/32; H01L 24/73; H01L 2224/06135; H01L 2224/32145; H01L 2224/32225; H01L 2224/48091; H01L 2224/48149; H01L 2224/48229; H01L 2224/4903; H01L 2224/73265; H01L 2225/06506; H01L 2225/0651; H01L 2225/06562; H01L 2924/1431; H01L 2924/14361

(57) ABSTRACT

A semiconductor package includes a base substrate, a first semiconductor chip, a second semiconductor chip, a first voltage bonding wire, a second voltage bonding wire and a first capacitance-sharing bonding wire. The base substrate includes substrate pads. The first semiconductor chip is stacked on the base substrate in a vertical direction and includes first chip pads. The second semiconductor chip is stacked on the first semiconductor chip in the vertical direction and includes second chip pads. The first voltage bonding wire electrically connects a first substrate voltage pad of the substrate pads and a first chip voltage pad of the first chip pads. The second voltage bonding wire electrically connects a second substrate voltage pad of the substrate pads and a second chip voltage pad of the second chip pads. The first capacitance-sharing bonding wire electrically connects the first chip voltage pad and the second chip voltage pad.

### CROSS-REFERENCE TO RELATED APPLICATION

This U.S. non-provisional application claims priority under 35 USC § 119 to Korean Patent Application No. 10-2024-0074197, filed on Jun. 7, 2024, in the Korean Intellectual Property Office (KIPO), the disclosure of which is incorporated by reference herein in its entirety.

### BACKGROUND

A typical stacked semiconductor package has a structure in which semiconductor chips (or semiconductor dies) are stacked. For example, a stacked semiconductor package may include semiconductor chips stacked on a base substrate such as a printed circuit board (PCB). By connecting the connection pads formed on the semiconductor chips with bonding wires, the semiconductor chips may be electrically connected to each other. A logic chip controlling the semiconductor chips may be included in the stacked semiconductor chips.

In recent years, the electronics market has seen a dramatic increase in the demand for portable devices, which has led to a continuous need for miniaturization and lightweighting of the electronic components in these products. To realize the miniaturization and lightweight of these electronic components, not only technologies that reduce the individual size of the mounting components are required, but also semiconductor package technologies that integrate multiple individual devices into a single package. In particular, semiconductor packages that handle high-frequency signals require not only miniaturization but also excellent electrical characteristics.

### SUMMARY

Some example implementations may provide a semiconductor package having improved voltage characteristics.

According to example implementations, a semiconductor package includes a base substrate, a first semiconductor chip, a second semiconductor chip, a first voltage bonding wire, a second voltage bonding wire and a first capacitance-sharing bonding wire.

The base substrate includes substrate pads. The first semiconductor chip is stacked on the base substrate in a vertical direction and includes first chip pads. The second semiconductor chip is stacked on the first semiconductor chip in the vertical direction and includes second chip pads. The first voltage bonding wire electrically connects a first substrate voltage pad of the substrate pads and a first chip voltage pad of the first chip pads, wherein a power supply voltage or a ground voltage is configured to be applied to the first substrate voltage pad. The second voltage bonding wire electrically connects a second substrate voltage pad of the substrate pads and a second chip voltage pad of the second chip pads, wherein the power supply voltage or the ground voltage is configured to be applied to the second substrate voltage pad. The first capacitance-sharing bonding wire electrically connects the first chip voltage pad and the second chip voltage pad.

According to example implementations, a semiconductor package includes a base substrate including substrate voltage pads, a plurality of semiconductor chips that are sequentially stacked on the base substrate in a vertical direction and each including chip pads, voltage bonding wires electrically connecting each substrate voltage pad of the substrate voltage pads and each chip voltage pad of the chip pads, wherein a power supply voltage or a ground voltage is applied to a first substrate voltage pad of the substrate voltage pads, and capacitance-sharing bonding wires each electrically connecting chip voltage pads included in different semiconductor chips among the plurality of semiconductor chips.

According to example implementations, a semiconductor package includes a base substrate including substrate pads, a first memory semiconductor chip stacked on the base substrate in a vertical direction and including first chip pads, a second memory semiconductor chip stacked on the first memory semiconductor chip in the vertical direction and including second chip pads, a first voltage bonding wire electrically connecting a first substrate voltage pad of the substrate pads and a first chip voltage pad of the first chip pads, wherein a power supply voltage is configured to be applied to the first substrate voltage pad, a second voltage bonding wire electrically connecting a second substrate voltage pad of the substrate pads and a second chip voltage pad of the second chip pads, wherein the power supply voltage is configured to be applied to the second substrate voltage pad, and a capacitance-sharing bonding wire electrically connecting the first chip voltage pad and the second chip voltage pad. One of the first memory semiconductor chip or the second memory semiconductor chip is configured to be selectively activated based on chip selection signals.

The semiconductor package according to example implementations may improve the voltage characteristics of the semiconductor package by electrically connecting the voltage pads of stacked semiconductor chips using capacitance-sharing bonding wires to increase the capacitance of each voltage pad.

### BRIEF DESCRIPTION OF THE DRAWINGS

Example implementations will be more clearly understood from the following detailed description taken in conjunction with the accompanying drawings.

FIG. 1 is a perspective view illustrating a semiconductor package according to example implementations.

FIG. 2 is a top view of the semiconductor package of FIG. 1, and FIGS. 3 and 4 are cross-sectional views of the semiconductor package of FIG. 1.

FIGS. 5 and 6 are diagrams illustrating capacitance of pads included in a semiconductor package according to example implementations.

FIG. 7 is a block diagram illustrating a memory system according to example implementations.

FIG. 8 is a block diagram illustrating a semiconductor memory device according to example implementations.

FIG. 9 is a diagram illustrating an example implementation of a bank array included in a semiconductor memory device according to example implementations.

FIG. 10 is a perspective view illustrating a semiconductor package according to example implementations.

FIG. 11 is a top view of the semiconductor package of FIG. 10, and FIGS. 12 and 13 are cross-sectional views of the semiconductor package of FIG. 10.

FIG. 14 is a perspective view illustrating a semiconductor package according to example implementations.

FIG. 15 is a top view of the semiconductor package of FIG. 14, and FIG. 16 is a cross-sectional view of the semiconductor package of FIG. 14.

FIG. 17 is a perspective view illustrating a semiconductor package according to example implementations.

FIG. 18 is a top view of the semiconductor package of FIG. 17, and FIG. 19 is a cross-sectional view of the semiconductor package of FIG. 19.

FIG. 20 is a cross-sectional view illustrating a semiconductor package according to example implementations.

FIGS. 21A and 21B are perspective views illustrating a semiconductor package according to example implementations.

FIGS. 22 and 23 are top views illustrating a semiconductor package according to example implementations.

FIG. 24 is a top view illustrating a s semiconductor package according to example implementations, and FIG. 25 is a cross-sectional view illustrating a semiconductor chip included in the semiconductor package of FIG. 24.

FIG. 26 is a diagram illustrating a stacked memory device according to example implementations.

FIG. 27 is a diagram illustrating a semiconductor package including a stacked memory device according to example implementations.

FIG. 28 is a block diagram illustrating a mobile system according to example implementations.

### DETAILED DESCRIPTION

Various example implementations will be described more fully hereinafter with reference to the accompanying drawings, in which some example implementations are shown. In the drawings, like numerals refer to like elements throughout. The repeated descriptions may be omitted.

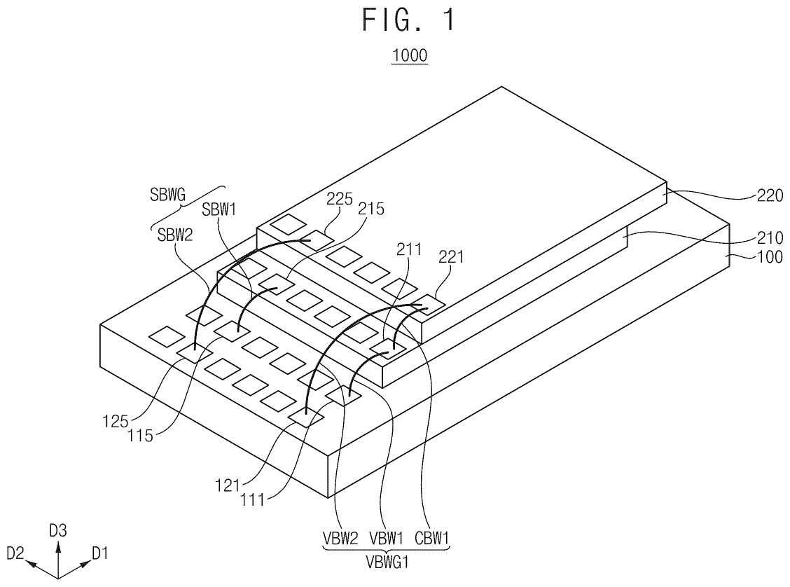

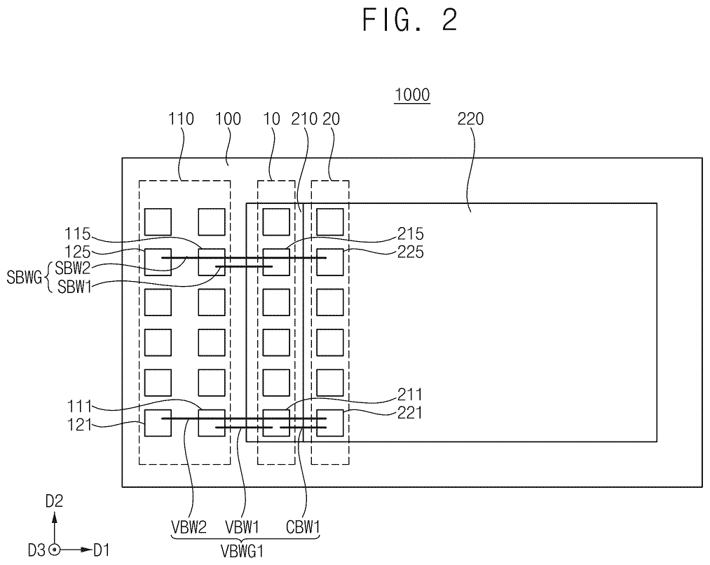

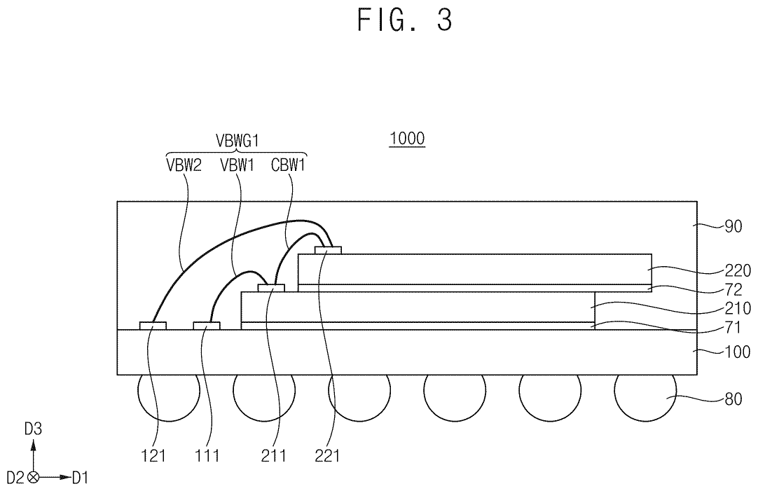

FIG. 1 is a perspective view illustrating a semiconductor package according to example implementations, FIG. 2 is a top view of the semiconductor package of FIG. 1, and FIGS. 3 and 4 are cross-sectional views of the semiconductor package of FIG. 1.

In FIGS. 1 through 4, two directions parallel to a top surface of a base substrate and intersecting each other are defined as a first direction D1 and a second direction D2, and a direction substantially perpendicular to the top surface of the base substrate is defined as a third direction D3. For example, the first direction D1 and the second direction D2 may intersect substantially perpendicular to each other. The third direction D3 may also be referred to as a vertical direction, the first direction D1 as a first horizontal direction, and the second direction D2 as a second horizontal direction. The first direction D1, the second direction D2, and the third direction D3 refer to the directions indicated by the arrows in the drawings, and the opposite directions of the first direction D1, the second direction D2, and the third direction D3 may be distinguished from the first direction D1, the opposite direction of the second direction D2, and the opposite direction of the third direction D3, respectively. The definitions of the aforementioned directions are the same in all subsequent drawings.

Referring to FIGS. 1 through 4, a semiconductor package 1000 may include a base substrate 100, a first semiconductor chip 210, a second semiconductor chip 220, a first voltage bonding wire VBW1, a second voltage bonding wire VBW2, and a first capacitance-sharing bonding wire CBW1.

The base substrate 100 includes substrate pads 110. The substrate pads 110 may include substrate voltage pads 111, 121 to which a power supply voltage or a ground voltage is applied, and substrate input-output pads 115, 125 for transmitting and receiving signals, such as data signals, control signals, etc. The base substrate 100 may be a printed circuit board (PCB), interposer, or the like having conductive lines designed on its top surface, interior, or the like.

In some implementations, a power supply voltage or a ground voltage is applied to the external terminal 80 from an external device, and the substrate voltage pads 111, 121 may be electrically connected to the external terminal 80 where the power supply voltage or the ground voltage is applied via conductive paths formed on the base substrate 100.

The first semiconductor chip 210 is stacked on the base substrate 100 in a vertical direction D3 and includes first chip pads 10. The first chip pads 10 may include a first chip voltage pad 211 for carrying a power supply voltage or a ground voltage and a first chip input-output pad 215 for transmitting and/or receiving signals.

A second semiconductor chip 220 is stacked on the first semiconductor chip 210 in the vertical direction D3 and includes second chip pads 20. The second chip pads 20 may include a second chip voltage pad 221 for carrying a power supply voltage or a ground voltage, and a second chip input-output pad 225 for transmitting and/or receiving signals.

The same voltage may be applied to the first substrate voltage pad 111 and the second substrate voltage pad 121. In other words, the first substrate voltage pad 111 and the second substrate voltage pad 121 may be pads with the common power supply voltage or pads with the common ground voltage.

The first voltage bonding wire VBW1 may electrically connect the first substrate voltage pad 111 of the substrate pads 110 to which the power supply voltage or the ground voltage is applied, and the first chip voltage pad 211 of the first chip pads 10.

The second voltage bonding wire VBW2 may electrically connect the second substrate voltage pad 121 of the substrate pads 110 to which the power supply voltage or the ground voltage is applied, and the second chip voltage pad 221 of the second chip pads 20.

The first capacitance-sharing bonding wire CBW1 may electrically connect the first chip voltage pad 211 and the second chip voltage pad 221.

The first voltage bonding wire VBW1, the second voltage bonding wire VBW2, and the first capacitance-sharing bonding wire CBW1 may be referred to as a voltage bonding wire group VBWG1. While one voltage bonding wire group VBWG1 is shown in FIGS. 1, 2, and 3 for convenience of illustration, the semiconductor package 1000 may include multiple voltage bonding wire groups having the same structure as the voltage bonding wire group VBWG1.

In addition, the semiconductor package 1000 may include a first signal bonding wire SBW1 and a second signal bonding wire SBW2.

The first signal bonding wire SBW1 may electrically connect a first substrate input-output pad 115 of the substrate pads 110 and a first chip input-output pad 215 of the first chip pads 10.

The second signal bonding wire SBW2 may electrically connect the second substrate input-output pad 125 of the substrate pads 110 and the second chip input-output pad 225 of the second chip pads 20.

For example, the first substrate input-output pad 115 and the first chip input-output pad 215 may be pads carrying a first chip select signal for selecting the first semiconductor chip 210, and the second substrate input-output pad 125 and the second chip input-output pad 225 may be pads carrying a second chip select signal for selecting the second semiconductor chip 220.

While the first chip voltage pad 211 and the second chip voltage pad 221 are electrically connected via the first capacitance-sharing bonding wire CBW1, the first chip input-output pad 215 and the second chip input-output pad 225 may be electrically isolated from each other. In other words, the bonding wires for signal transfer only connect the base substrate and the respective semiconductor chips, and the signal bonding wires connecting the stacked semiconductor chips may be omitted.

The first signal bonding wire SBW1 and the second signal bonding wire SBW2 may be referred to as a signal bonding wire group SBWG. While one signal bonding wire group SBWG is shown in FIGS. 1, 2, and 4 for convenience of illustration, the semiconductor package 1000 may include multiple signal bonding wire groups having the same structure as the signal bonding wire group SBWG.

The base substrate 100 and the semiconductor chips may be stacked using adhesive layers 71 and 72. The first semiconductor chip 210 may be bonded to a top surface of the base substrate 100 via the first adhesive layer 71, and the second semiconductor chip 220 may be bonded to a top surface of the first semiconductor chip 210 via the second adhesive layer 72.

The external terminals 80 may be provided on the lower surface of the base substrate 100. The external terminals 80 may include solder balls or solder pads, and depending on the type of external terminals 80, the semiconductor package 1000 may include a ball grid array (BGA), a fine ball-grid array (FBGA), a land grid array (LGA), or the like.

The molding film 90 may be provided to cover the top surface of the base substrate 100 and the semiconductor chips 210 and 220. The molding film 90 may include an insulating polymeric material, such as an epoxy molding compound (EMC).

As shown in FIGS. 1 through 4, the substrate pads 110 may be arranged along a second horizontal direction D2 on at least one of an end portion of the base substrate 100 in a first horizontal direction D1 and an end portion of the base substrate 100 in the opposite direction of the first horizontal direction D1.

The first chip pads 10 may be arranged along the second horizontal direction D2 at an end portion of the first semiconductor chip 210 in the opposite direction of the first horizontal direction D1.

The second chip pads 20 may be arranged along the second horizontal direction D2 at an end portion of the second semiconductor chip 220 in the opposite direction of the first horizontal direction D1.

The second semiconductor chip 220 may be offset in the first horizontal direction D1 relative to the first semiconductor chip 210 such that the first chip pads 10 are exposed toward the vertical direction D3, i.e., such that the second semiconductor chip 220, which is stacked on the first semiconductor chip 210, does not cover the first chip pads 10.

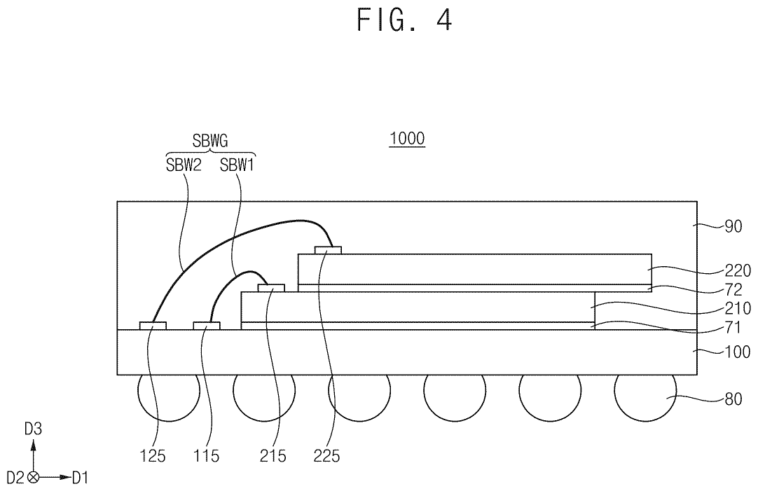

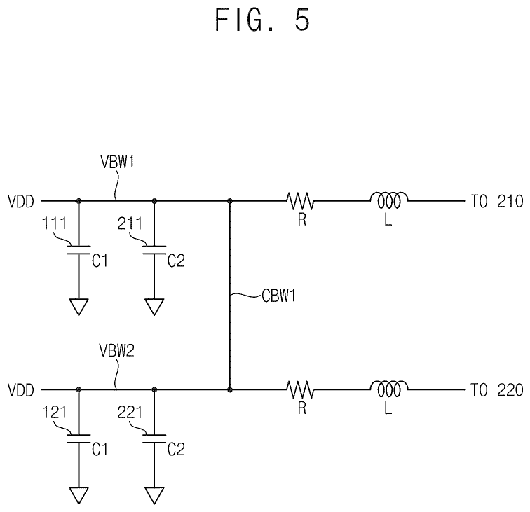

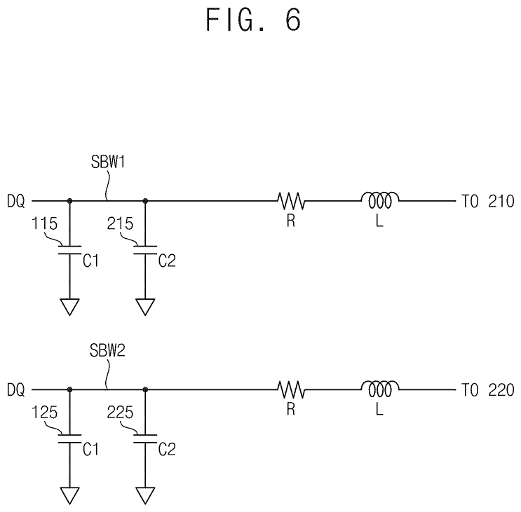

FIGS. 5 and 6 are diagrams illustrating capacitance of pads included in a semiconductor package according to example implementations.

FIG. 5 illustrates the equivalent impedance along a voltage transmission path by a voltage bonding wire group VBWG1 described with reference to FIGS. 1 through 4, and FIG. 6 illustrates the equivalent impedance along a signal transfer path by a signal bonding wire group SBWG described with reference to FIGS. 1 through 4.

Referring to FIG. 5, the first chip voltage pad 211 of the first semiconductor chip 210 and the second chip voltage pad 221 of the second semiconductor chip 220 are electrically connected via the first capacitance-sharing bonding wire CBW1. In this case, the first chip voltage pad 211 and the second chip voltage pad 221 are connected in parallel, which increases the capacitance. As a result, the first substrate voltage pad 111, the second substrate voltage pad 121, the first chip voltage pad 211, and the second chip voltage pad 221 share a capacitance such that the shared capacitance of each pad is equal to 2(C1+C2).

As the power dissipation of the semiconductor chips 210 and 220 increases, the peak current increases and the voltage drop along the voltage transmission path increases, resulting in a ripple phenomenon that lowers the voltage level. The effect of this capacitance sharing may be minimal if the semiconductor chips 210 and 220 are in the active state simultaneously. However, for example, when the semiconductor chips 210 and 220 are memory semiconductor chips belonging to a single channel, the memory semiconductor chips are selectively activated based on their respective chip select signals. In this case, one memory semiconductor chip in the active state consumes power, while the power consumption of the remaining memory semiconductor chips in the idle state is negligible. As a result, the power supply voltage supplied to the memory semiconductor chips in the active state may be stabilized by capacitance sharing, and the voltage characteristics of the semiconductor package may be improved.

Conventionally, passive devices such as land-side capacitors (LSCs) placed on the side of the base substrate, die-side capacitors (DSCs) placed on the bottom of the base substrate, and embedded type capacitors embedded inside the base substrate have been used to increase the capacitance along the voltage transmission path. The inclusion of such passive elements increases the occupied area of the semiconductor package and reduces the design margin.

According to example implementations, voltage characteristics may be further improved by connecting additional passive devices such as LSCs and DSCs in addition to the first capacitance-sharing bonding wire CBW1 described with reference to FIGS. 1 to 4.

According to example implementations, by electrically connecting the voltage pads of the stacked semiconductor chips using capacitance-sharing bonding wires, the capacitance of each voltage pad may be increased, and the voltage characteristics of the semiconductor package may be improved without increasing the occupied area of the semiconductor package.

Referring to FIG. 6, the first chip input-output pad 215 of the first semiconductor chip 210 and the second chip input-output pad 225 of the second semiconductor chip 220 may be electrically disconnected without being connected by bonding wires. Parasitic impedance along the signal transfer path may degrade the high frequency characteristics. Thus, while the voltage transfer path of FIG. 5 includes a first capacitance-sharing bonding wire CBW1 for capacitance sharing, the signal transfer path of FIG. 6 may omit bonding wires connecting the pads of the different chips.

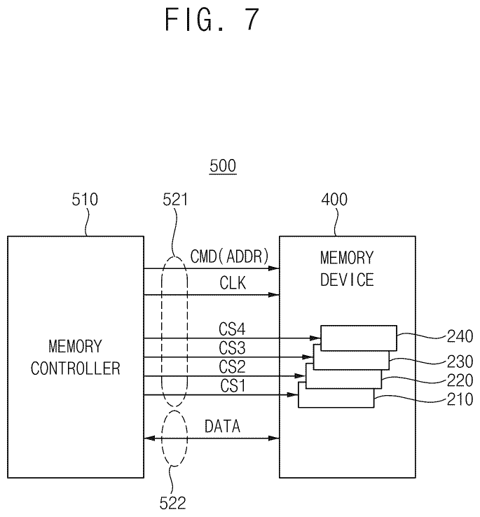

FIG. 7 is a block diagram illustrating a memory system according to example implementations.

Referring to FIG. 7, a memory system 500 includes a memory controller 510 and a semiconductor memory device 400. Each of the memory controller 510 and the semiconductor memory device 400 includes an interface for communicating with each other.

The interfaces may be connected via a control bus 521 for transmitting a command CMD, an access address ADDR, a clock signal CLK, and the like, and a data bus 522 for transmitting data.

Depending on the type of semiconductor memory device, a command CMD may be considered to include an access address ADDR. The memory controller 510 generates command signals to control the semiconductor memory device 400, and under the control of the memory controller 510, data may be written to the semiconductor memory device 400 or data may be read from the semiconductor memory device 400.

The semiconductor memory device 400 may be implemented in the form of a semiconductor package in which a plurality of semiconductor chips 210, 220, 230 and 240 are stacked, as described with reference to FIGS. 1 through 4. The plurality of semiconductor chips 210, 220, 230 and 240 may be selectively enabled or activated based on each of the plurality of chip select signals CS1, CS2, CS3 and CS4. If the plurality of semiconductor chips 210, 220, 230 and 240 belong to one and the same channel, only one of the plurality of chip select signals CS1, CS2, CS3 and CS4 may be enabled and the others may be disabled.

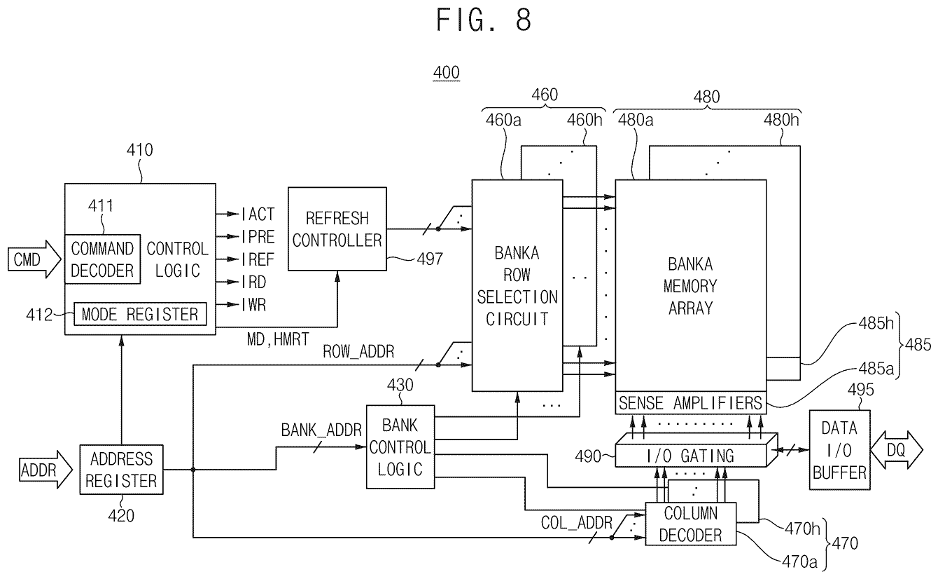

FIG. 8 is a block diagram illustrating a semiconductor memory device according to example implementations.

Referring to FIG. 8, a memory device 400 may include a command control logic 410, an address register 420, a bank control logic 430, a row selection circuit 460 (or row decoder), a column decoder 470, a memory cell array 480, a sense amplifier unit 485, an input-output (I/O) gating circuit 490, a data input-output (I/O) buffer 495, and a refresh controller 497.

The memory cell array 480 may include a plurality of bank arrays 480a, . . . , 480h. The row selection circuit 460 may include a plurality of bank row selection circuits 460a, . . . , 460h respectively coupled to the bank arrays 480a, . . . , 480h. The column decoder 470 may include a plurality of bank column decoders 470a, . . . , 470h respectively coupled to the bank arrays 480a, . . .. 480h. The sense amplifier unit 485 may include a plurality of bank sense amplifiers 485a, . . . , 485h respectively coupled to the bank arrays 480a, . . . , 480h.

The address register 420 may receive an address ADDR including a bank address BANK_ADDR, a row address ROW_ADDR, and a column address COL_ADDR from the memory controller 50. The address register 420 may provide the received bank address BANK_ADDR to the bank control logic 430, may provide the received row address ROW_ADDR to the row selection circuit 460, and may provide the received column address COL_ADDR to the column decoder 470.

The bank control logic 430 may generate bank control signals in response to the bank address BANK_ADDR. One of the bank row selection circuits 460a, . . . , 460h corresponding to the bank address BANK_ADDR may be activated in response to the bank control signals, and one of the bank column decoders 470a, . . . , 470h corresponding to the bank address BANK_ADDR may be activated in response to the bank control signals.

The row address ROW_ADDR from the address register 420 may be applied to the bank row selection circuits 460a, . . . , 460h. The activated one of the bank row selection circuits 460a, . . . , 460h may decode the row address ROW_ADDR, and may activate a wordline corresponding to the row address ROW_ADDR. For example, the activated bank row selection circuit 460 may apply a wordline driving voltage to the wordline corresponding to the row address ROW_ADDR.

The column decoder 470 may include a column address latch. The column address latch may receive the column address COL_ADDR from the address register 420, and may temporarily store the received column address COL_ADDR. In some example implementations, in a burst mode, the column address latch may generate column addresses that increment from the received column address COL_ADDR. The column address latch may apply the temporarily stored or generated column address to the bank column decoders 470a, . . . , 470h.

The activated one of the bank column decoders 470a, . . . , 470h may decode the column address COL_ADDR, and may control the I/O gating circuit 490 in order to output data corresponding to the column address COL_ADDR.

The I/O gating circuit 490 may include circuitry for gating input-output data. The I/O gating circuit 490 may further include read data latches for storing data that is output from the bank arrays 480a, . . . , 480h, and write drivers for writing data to the bank arrays 480a, . . . , 480h.

Data to be read from one bank array of the bank arrays 480a, . . . , 480h may be sensed by one of the bank sense amplifiers 485a, . . . , 485h coupled to the one bank array from which the data is to be read, and may be stored in the read data latches. The data stored in the read data latches may be provided to the memory controller 510 via the data I/O buffer 495. Data DQ to be written in one bank array of the bank arrays 480a, . . . , 480h may be provided to the data I/O buffer 495 from the memory controller 510. The write driver may write the data DQ in one bank array of the bank arrays 480a, . . . , 480h.

The command control logic 410 may control operations of the memory device 400. For example, the command control logic 410 may generate control signals for the memory device 400 in order to perform a write operation, a read operation, or a refresh operation. The command control logic 410 may generate internal command signals such as an active signal IACT, a precharge signal IPRE, a refresh signal IREF, a read signal IRD, a write signal IWR, etc., based on commands CMD transferred from the memory controller 510 in FIG. 7. The command control logic 410 may include a command decoder 411 that decodes the commands CMD received from the memory controller 510 and a mode register set 412 that sets an operation mode of the memory device 400.

Although FIG. 8 illustrates the command control logic 410 and the address register 420 as being distinct from each other, the command control logic 410 and the address register 420 may be implemented as a single integrated circuit. In addition, although FIG. 8 illustrates the command CMD and the address ADDR being provided as distinct signals, the command CMD and the address ADDR may be provided as a combined signals, e.g., as specified by DDR5, HBM and LPDDR5 standards.

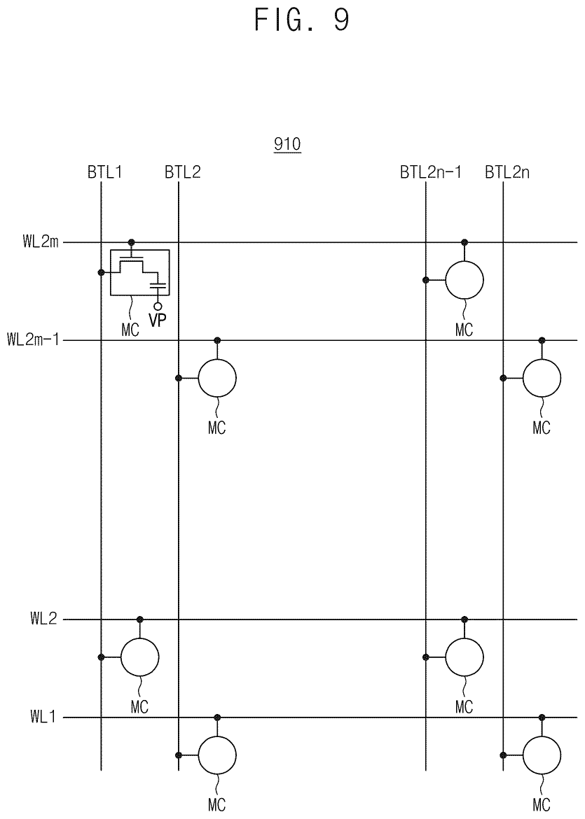

FIG. 9 is a diagram illustrating an example implementation of a bank array included in a semiconductor memory device according to example implementations.

Referring to FIG. 9, a bank array 910 includes a plurality of wordlines WL1˜WL2m (where m is a natural number greater than two), a plurality of bitlines BTL1˜BTL2n (where n is a natural number greater than two), and a plurality of memory cells MCs disposed near intersections between the wordlines WL1˜WL2m and the bitlines BTL1˜BTL2n. In some example implementations, each of the plurality of memory cells MCs may include a DRAM cell structure as illustrated in FIG. 9. The memory cell MC may include a cell capacitor connected to the plate voltage VP and a cell transistor connected between each bitline and the cell capacitor, and the gate electrode of the cell transistor is connected to each wordline. The plurality of wordlines WL1˜WL2m to which the plurality of memory cells MCs are connected may be referred to as rows of the bank array 910 and the plurality of bitlines BL1˜BL3n to which the plurality of memory cells MCs are connected may be referred to as columns of the bank array 910.

The semiconductor chips described above may be memory semiconductor chips on which semiconductor memory devices are integrated. The semiconductor memory devices integrated on the semiconductor chips may be DRAM devices as described with reference to FIGS. 8 and 9, but example implementations are not limited to any particular type of memory.

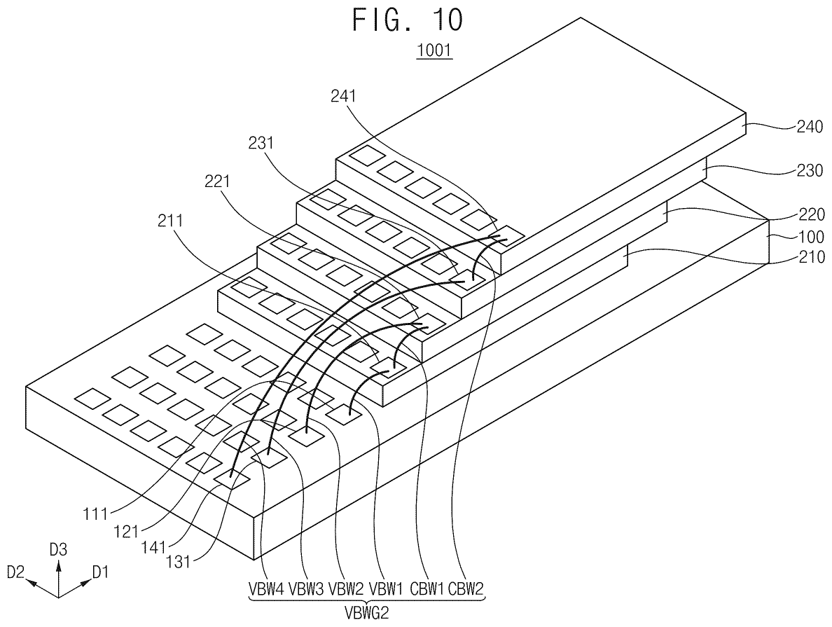

Referring now to FIGS. 10 through 19, example implementations of a semiconductor package in which four semiconductor chips are stacked will be described. Example implementations are not limited to a particular number of semiconductor chips that are stacked, and the number of semiconductor chips included in a semiconductor package may be varied, such as two, four, eight, sixteen, or the like.

Hereinafter, example implementations will be described focusing on the configuration and arrangement of the voltage bonding wire group, omitting the illustration and description of the signal bonding wire group SBWG described with reference to FIGS. 1, 2 and 4.

FIG. 10 is a perspective view illustrating a semiconductor package according to example implementations, FIG. 11 is a top view of the semiconductor package of FIG. 10, and FIGS. 12 and 13 are cross-sectional views of the semiconductor package of FIG. 10.

Referring to FIGS. 10, 11, and 12, a semiconductor package 1001 includes a base substrate 100, a first semiconductor chip 210, a second semiconductor chip 220, a third semiconductor chip 230, a fourth semiconductor chip 240, and a first voltage bonding wire VBW1, a second voltage bonding wire VBW2, a third voltage bonding wire VBW3, a fourth voltage bonding wire VBW4, a first capacitance-sharing bonding wire CBW1, and a second capacitance-sharing bonding wire CBW2.

The base substrate 100 includes substrate pads 110. The substrate pads 110 may include substrate voltage pads 111, 121, 131 and 141 to which a power supply voltage or a ground voltage is applied. The base substrate 100 may be a printed circuit board (PCB), interposer, or the like having conductive lines designed on its top surface, interior, or the like.

The first semiconductor chip 210 is stacked on the base substrate 100 in the vertical direction D3 and includes first chip pads 10. The first chip pads 10 may include a first chip voltage pad 211 that carries a power supply voltage or a ground voltage.

The second semiconductor chip 220 is stacked on the first semiconductor chip 210 in a vertical direction D3 and includes second chip pads 20. The second chip pads 20 may include a second chip voltage pad 221 that carries the power supply voltage or the ground voltage.

The third semiconductor chip 230 is stacked on the second semiconductor chip 220 in the vertical direction D3 and includes third chip pads 30. The third chip pads 30 may include a third chip voltage pad 231 that carries the power supply voltage or the ground voltage.

The fourth semiconductor chip 240 is stacked on the third semiconductor chip 230 in the vertical direction D3 and includes fourth chip pads 40. The fourth chip pads 40 may include a fourth chip voltage pad 241 that carries the power supply voltage or the ground voltage.

The same voltage may be applied to the first substrate voltage pad 111, the second substrate voltage pad 121, the third substrate voltage pad 131, and the fourth substrate voltage pad 141. In other words, the first substrate voltage pad 111, the second substrate voltage pad 121, the third substrate voltage pad 131, and the fourth substrate voltage pad 141 may be pads with the common power supply voltage or pads with the common ground voltage.

The first voltage bonding wire VBW1 may electrically connect the first substrate voltage pad 111 of the substrate pads 110 to which the power supply voltage or the ground voltage is applied, and the first chip voltage pad 211 of the first chip pads 10.

The second voltage bonding wire VBW2 may electrically connect the second substrate voltage pad 121 of the substrate pads 110 to which the power supply voltage or the ground voltage is applied, and the second chip voltage pad 221 of the second chip pads 20.

The third voltage bonding wire VBW3 may electrically connect the third substrate voltage pad 131 of the substrate pads 110 to which the power supply voltage or the ground voltage is applied, and the third chip voltage pad 231 of the third chip pads 30.

The fourth voltage bonding wire VBW4 may electrically connect the fourth substrate voltage pad 141 of the substrate pads 110 to which the power supply voltage or the ground voltage is applied, and the fourth chip voltage pad 241 of the fourth chip pads 40.

The first capacitance-sharing bonding wire CBW1 may electrically connect the first chip voltage pad 211 and the second chip voltage pad 221.

The second capacitance-sharing bonding wire CBW2 may electrically connect the third chip voltage pad 231 and the fourth chip voltage pad 241.

The first voltage bonding wire VBW1, the second voltage bonding wire VBW2, the third voltage bonding wire VBW3, the fourth voltage bonding wire VBW4, the first capacitance-sharing bonding wire CBW1, and the second capacitance-sharing bonding wire CBW2 may be referred to as the voltage bonding wire group VBWG2. While one voltage bonding wire group VBWG2 is shown in FIGS. 10, 11, and 12 for convenience of illustration, the semiconductor package 1001 may include multiple voltage bonding wire groups having the same structure as the voltage bonding wire group VBWG2.

The base substrate 100 and the semiconductor chips may be stacked using adhesive layers 71, 72, 73, and 74. A first semiconductor chip 210 may be bonded to the top surface of the base substrate 100 via the first adhesive layer 71, a second semiconductor chip 220 may be bonded to the top surface of the first semiconductor chip 210 via the second adhesive layer 72, a third semiconductor chip 230 may be bonded to the top surface of the second semiconductor chip 220 via the third adhesive layer 73, and a fourth semiconductor chip 240 may be bonded to the top surface of the third semiconductor chip 230 via the fourth adhesive layer 74.

The external terminals 80 may be provided on the lower surface of the base substrate 100. The external terminals 80 may include solder balls or solder pads, and depending on the type of external terminals 80, the semiconductor package 1001 may include a ball grid array (BGA), a fine ball-grid array (FBGA), a land grid array (LGA), or the like.

The molded film 90 may be provided to cover the top surface of the base substrate 100 and the semiconductor chips 210, 220, 230, and 240. The molding film 90 may comprise an insulating polymeric material, such as an epoxy molding compound (EMC).

As shown in FIGS. 10, 11, and 12, the substrate pads 110 may be arranged along a second horizontal direction D2 on at least one of an end portion of the base substrate 100 in the first horizontal direction D1 and an end portion of the base substrate 100 in the opposite direction of the first horizontal direction D1.

The first chip pads 10 may be arranged along the second horizontal direction D2 at an end portion of the first semiconductor chip 210 in the opposite direction of the first horizontal direction D1.

The second chip pads 20 may be arranged along the second horizontal direction D2 at an end portion of the second semiconductor chip 220 in the opposite direction of the first horizontal direction D1.

The third chip pads 30 may be arranged along the second horizontal direction D2 at an end portion of the third semiconductor chip 230 in an opposite direction of the first horizontal direction D1.

The fourth chip pads 40 may be arranged along the second horizontal direction D2 at an end portion of the fourth semiconductor chip 240 in the opposite direction of the first horizontal direction D1.

The second semiconductor chip 220 may be offset in a first horizontal direction D1 relative to the first semiconductor chip 210 such that the first chip pads 10 are exposed toward the vertical direction D3, i.e., such that the second semiconductor chip 220, which is stacked on the first semiconductor chip 210, does not cover the first chip pads 10.

The third semiconductor chip 230 may be offset in the first horizontal direction D1 relative to the second semiconductor chip 220 such that the second chip pads 20 are exposed toward the vertical direction D3.

The fourth semiconductor chip 240 may be offset in the first horizontal direction D1 relative to the third semiconductor chip 230 such that the third chip pads 30 are exposed toward the vertical direction D3.

The semiconductor package 1001a of FIG. 13 is substantially the same as the semiconductor package 1001 described with reference to FIGS. 10, 11, and 12, so redundant descriptions will be omitted and only differences will be described.

Referring to FIG. 13, the semiconductor package 1001a may further include a third capacitance-sharing bonding wire CBW3 electrically connecting the second chip voltage pad 221 and the third chip voltage pad 231. By adding the third capacitance-sharing bonding wire CBW3, the capacitance sharing along the voltage transfer path may be further enhanced.

The first voltage bonding wire VBW1, the second voltage bonding wire VBW2, the third voltage bonding wire VBW3, the fourth voltage bonding wire VBW4, the first capacitance-sharing bonding wire CBW1, the second capacitance-sharing bonding wire CBW2, and the third capacitance-sharing bonding wire CBW3 may be referred to as a voltage bonding wire group VBWG3. The semiconductor package 1001a may include multiple voltage bonding wire groups having the same structure as the voltage bonding wire group VBWG3.

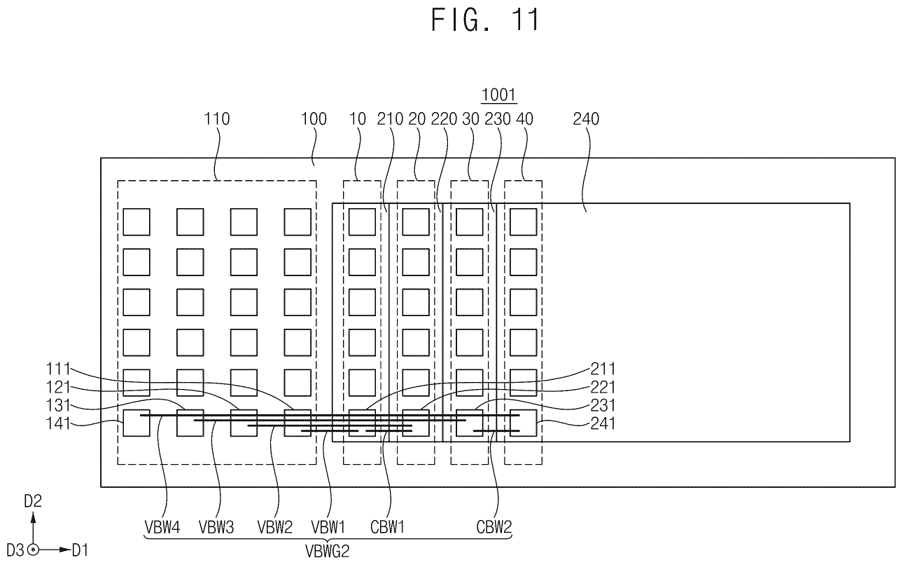

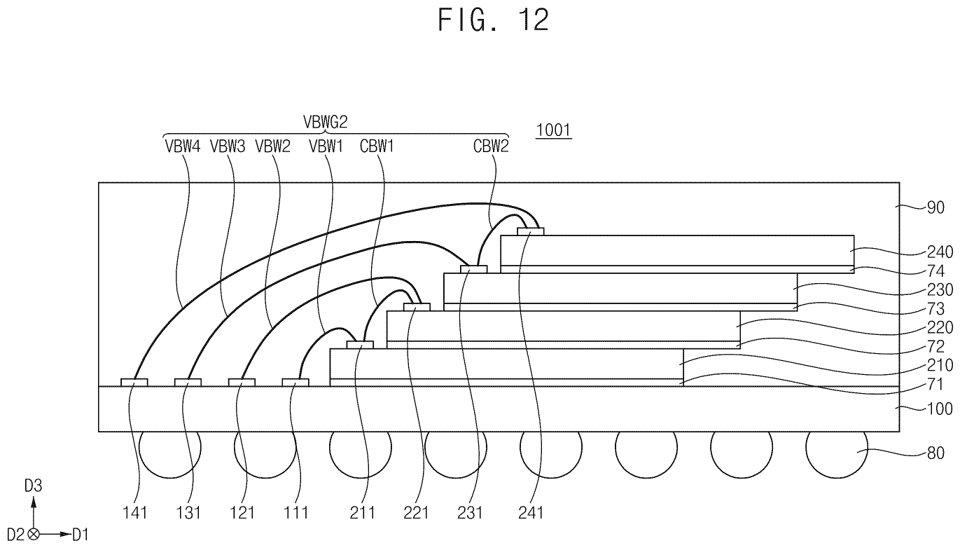

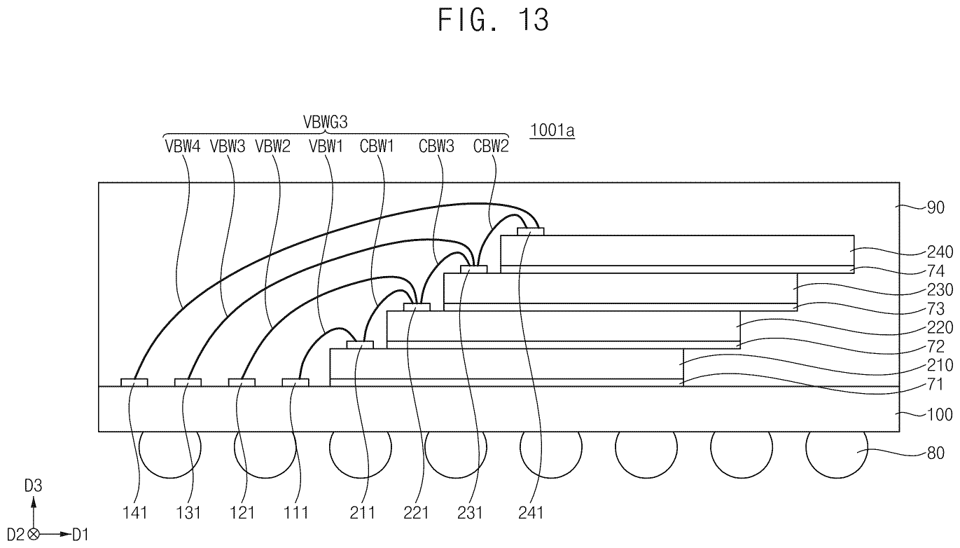

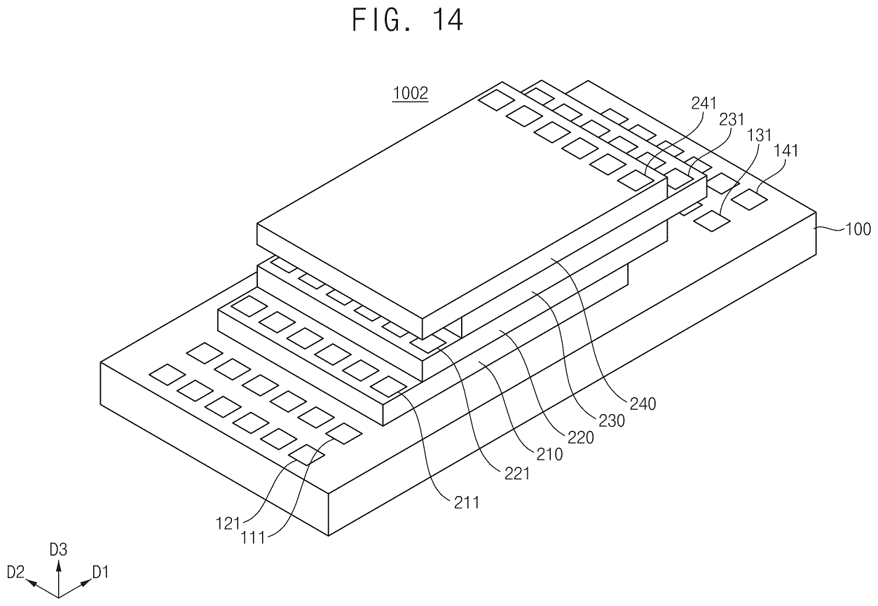

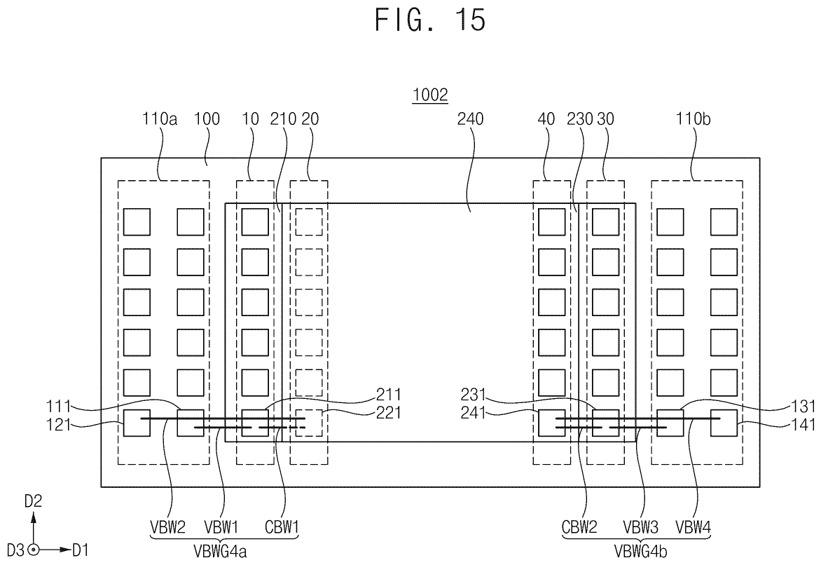

FIG. 14 is a perspective view illustrating a semiconductor package according to example implementations, FIG. 15 is a top view of the semiconductor package of FIG. 14, and FIG. 16 is a cross-sectional view of the semiconductor package of FIG. 14.

Referring to FIGS. 14, 15, and 16, a semiconductor package 1002 includes a base substrate 100, a first semiconductor chip 210, a second semiconductor chip 220, a third semiconductor chip 230, a fourth semiconductor chip 240, and a first voltage bonding wire VBW1, a second voltage bonding wire VBW2, a third voltage bonding wire VBW3, a fourth voltage bonding wire VBW4, a first capacitance-sharing bonding wire CBW1, and a second capacitance-sharing bonding wire CBW2.

The base substrate 100 includes substrate pads 110a and 110b. The substrate pads 110a and 110b may include substrate voltage pads 111, 121, 131 and 141 to which a power supply voltage or a ground voltage is applied. The base substrate 100 may be a printed circuit board (PCB), interposer, or the like having conductive lines designed on its top surface, interior, or the like.

The first semiconductor chip 210 is stacked on the base substrate 100 in a vertical direction D3 and includes first chip pads 10. The first chip pads 10 may include a first chip voltage pad 211 that carries the power supply voltage or the ground voltage.

The second semiconductor chip 220 is stacked on the first semiconductor chip 210 in the vertical direction D3 and includes second chip pads 20. The second chip pads 20 may include a second chip voltage pad 221 that carries the power supply voltage or the ground voltage.

The third semiconductor chip 230 is stacked on the second semiconductor chip 220 in the vertical direction D3 and includes third chip pads 30. The third chip pads 30 may include a third chip voltage pad 231 that carries the power supply voltage or the a ground voltage.

The fourth semiconductor chip 240 is stacked on the third semiconductor chip 230 in the vertical direction D3 and includes fourth chip pads 40. The fourth chip pads 40 may include a fourth chip voltage pad 241 that carries the power supply voltage or the ground voltage.

The same voltage may be applied to the first substrate voltage pad 111, the second substrate voltage pad 121, the third substrate voltage pad 131, and the fourth substrate voltage pad 141. In other words, the first substrate voltage pad 111, the second substrate voltage pad 121, the third substrate voltage pad 131, and the fourth substrate voltage pad 141 may be pads with the common power supply voltage or pads with the common ground voltage.

The first voltage bonding wire VBW1 may electrically connect the first substrate voltage pad 111 to which the power supply voltage or the ground voltage is applied, among the substrate pads 110a, and the first chip voltage pad 211 of the first chip pads 10.

The second voltage bonding wire VBW2 may electrically connect the second substrate voltage pad 121 of the substrate pads 110a to which the power supply voltage or the ground voltage is applied, and the second chip voltage pad 221 of the second chip pads 20.

The third voltage bonding wire VBW3 may electrically connect a third substrate voltage pad 131 of the substrate pads 110b to which the power supply voltage or the ground voltage is applied, and the third chip voltage pad 231 of the third chip pads 30.

The fourth voltage bonding wire VBW4 may electrically connect the fourth substrate voltage pad 141 of the substrate pads 110b to which the power supply voltage or the ground voltage is applied, and the fourth chip voltage pad 241 of the fourth chip pads 40.

The first capacitance-sharing bonding wire CBW1 may electrically connect the first chip voltage pad 211 and the second chip voltage pad 221.

The second capacitance-sharing bonding wire CBW2 may electrically connect the third chip voltage pad 231 and the fourth chip voltage pad 241.

The first voltage bonding wire VBW1, the second voltage bonding wire VBW2, the third voltage bonding wire VBW3, the fourth voltage bonding wire VBW4, the first capacitance-sharing bonding wire CBW1, and the second capacitance-sharing bonding wire CBW2 may be referred to as voltage bonding wire groups VBWG4a and VBWG4b, respectively. In FIG. 14, the voltage bonding wire groups VBWG4a and VBWG4b are omitted for convenience of simplicity. In FIGS. 15 and 16, one voltage bonding wire group VBWG4a and VBWG4b is shown for the convenience of illustration, but the semiconductor package 1002 may include multiple voltage bonding wire groups having the same structure as voltage bonding wire group VBWG4a and VBWG4b.

The base substrate 100 and the semiconductor chips may be stacked using adhesive layers 71, 72, 73 and 74. The first semiconductor chip 210 may be bonded to a top surface of the base substrate 100 via the first adhesive layer 71, the second semiconductor chip 220 may be bonded to a top surface of the first semiconductor chip 210 via the second adhesive layer 72, the third semiconductor chip 230 may be bonded to a top surface of the second semiconductor chip 220 via the third adhesive layer 73, and the fourth semiconductor chip 240 may be bonded to a top surface of the third semiconductor chip 230 via the fourth adhesive layer 74.

The external terminals 80 may be provided on the lower surface of the base substrate 100. The external terminals 80 may include solder balls or solder pads, and depending on the type of external terminals 80, the semiconductor package 1001 may include a ball grid array (BGA), a fine ball-grid array (FBGA), or a land grid array (LGA).

The molded film 90 may be provided to cover the top surface of the base substrate 100 and the semiconductor chips 210, 220, 230, and 240. The molding film 90 may include an insulating polymeric material such as an epoxy molding compound (EMC).

As shown in FIGS. 14, 15, and 16, the substrate pads 110a may be arranged along the second horizontal direction D2 at an end portion of the base substrate 100 in the opposite direction of the first horizontal direction D1, and the substrate pads 110b may be arranged along the second horizontal direction D2 at an end portion of the base substrate 100 in the first horizontal direction D1.

The first chip pads 10 may be arranged along the second horizontal direction D2 at an end portion of the first semiconductor chip 210 in the opposite direction of the first horizontal direction D1.

The second chip pads 20 may be arranged along the second horizontal direction D2 at an end portion of the second semiconductor chip 220 in the opposite direction of the first horizontal direction D1.

The third chip pads 30 may be arranged along the second horizontal direction D2 at an end portion of the third semiconductor chip 230 in the first horizontal direction D1.

The fourth chip pads 40 may be arranged along the second horizontal direction D2 at an end portion of the fourth semiconductor chip 240 in the first horizontal direction D1.

The second semiconductor chip 220 may be offset in the first horizontal direction D1 relative to the first semiconductor chip 210 such that the first chip pads 10 are exposed toward the vertical direction D3, i.e., such that the second semiconductor chip 220 that is stacked on the first semiconductor chip 210 does not cover the first chip pads 10.

The third semiconductor chip 230 may be offset in the first horizontal direction D1 relative to the second semiconductor chip 220 such that the second chip pads 20 are exposed toward the vertical direction D3.

The fourth semiconductor chip 240 may be offset in the opposite direction of the first horizontal direction D1 relative to the third semiconductor chip 230 such that the third chip pads 30 are exposed toward the vertical direction D3.

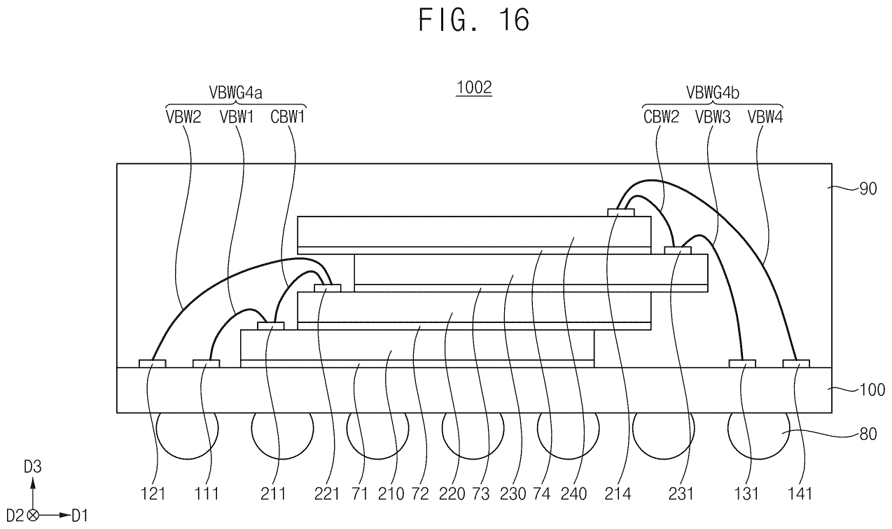

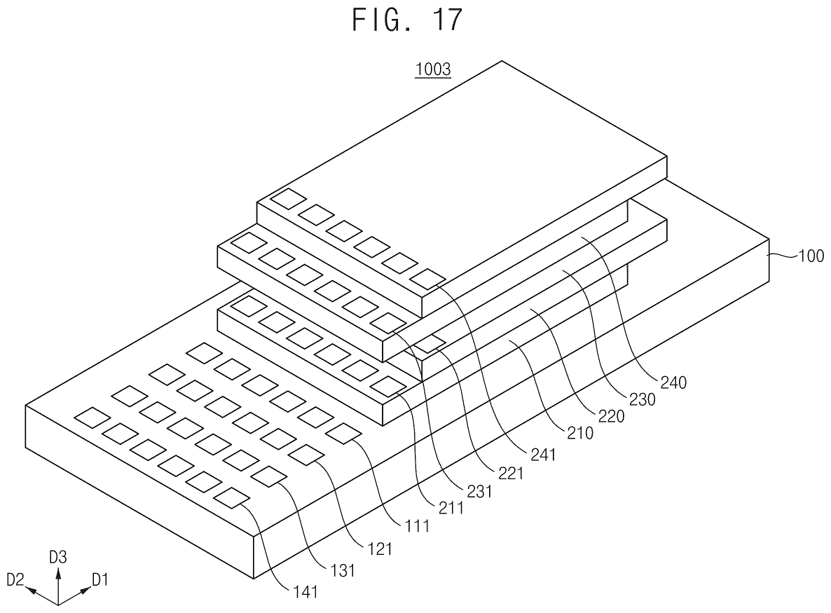

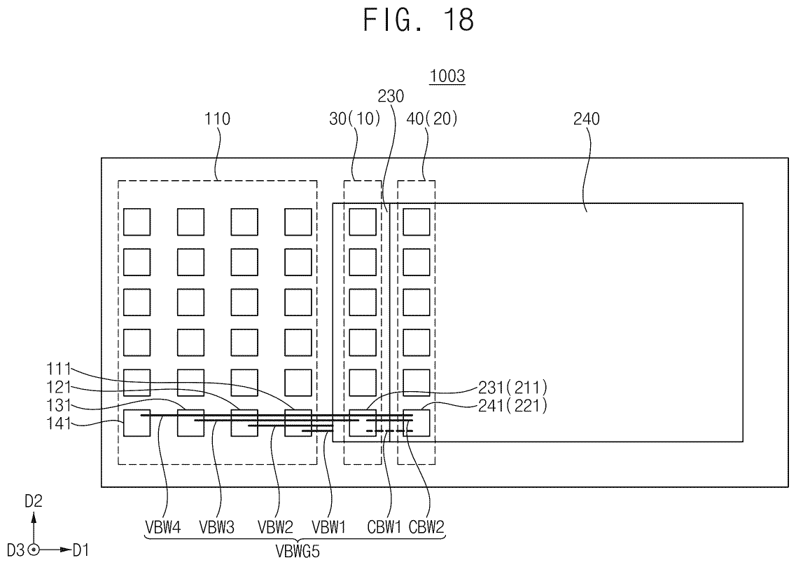

FIG. 17 is a perspective view illustrating a semiconductor package according to example implementations, FIG. 18 is a top view of the semiconductor package of FIG. 17, and FIG. 19 is a cross-sectional view of the semiconductor package of FIG. 17.

Referring to FIGS. 17, 18, and 19, a semiconductor package 1003 includes a base substrate 100, a first semiconductor chip 210, a second semiconductor chip 220, a third semiconductor chip 230, a fourth semiconductor chip 240, and a first voltage bonding wire VBW1, a second voltage bonding wire VBW2, a third voltage bonding wire VBW3, a fourth voltage bonding wire VBW4, a first capacitance-sharing bonding wire CBW1, and a second capacitance-sharing bonding wire CBW2.

The base substrate 100 includes substrate pads 110. The substrate pads 110 may include substrate voltage pads 111, 121, 131 and 141 to which the power supply voltage or the ground voltage is applied. The base substrate 100 may be a printed circuit board (PCB), interposer, or the like having conductive lines designed on its top surface, interior, or the like.

The first semiconductor chip 210 is stacked on the base substrate 100 in the vertical direction D3 and includes first chip pads 10. The first chip pads 10 may include a first chip voltage pad 211 that carries the power supply voltage or the ground voltage.

The second semiconductor chip 220 is stacked on the first semiconductor chip 210 in the vertical direction D3 and includes second chip pads 20. The second chip pads 20 may include a second chip voltage pad 221 that carries the power supply voltage or the ground voltage.

The third semiconductor chip 230 is stacked on the second semiconductor chip 220 in the vertical direction D3 and includes third chip pads 30. The third chip pads 30 may include a third chip voltage pad 231 that carries the power supply voltage or the ground voltage.

The fourth semiconductor chip 240 is stacked on the third semiconductor chip 230 in the vertical direction D3 and includes fourth chip pads 40. The fourth chip pads 40 may include a fourth chip voltage pad 241 that carries the power supply voltage or the ground voltage.

The same voltage may be applied to the first substrate voltage pad 111, the second substrate voltage pad 121, the third substrate voltage pad 131, and the fourth substrate voltage pad 141. In other words, the first substrate voltage pad 111, the second substrate voltage pad 121, the third substrate voltage pad 131, and the fourth substrate voltage pad 141 may be pads with the common power supply voltage or pads with the common ground voltage.

The first voltage bonding wire VBW1 may electrically connect the first substrate voltage pad 111 to which the power supply voltage or the ground voltage is applied, among the substrate pads 110, and the first chip voltage pad 211 of the first chip pads 10.

The second voltage bonding wire VBW2 may electrically connect the second substrate voltage pad 121 of the substrate pads 110 to which the power supply voltage or the ground voltage is applied, and the second chip voltage pad 221 of the second chip pads 20.

The third voltage bonding wire VBW3 may electrically connect a third substrate voltage pad 131 of the substrate pads 110 to which the power supply voltage or the ground voltage is applied, and a third chip voltage pad 231 of the third chip pads 30.

The fourth voltage bonding wire VBW4 may electrically connect the fourth substrate voltage pad 141 of the substrate pads 110 on which the power supply voltage or the ground voltage is applied, and the fourth chip voltage pad 241 of the fourth chip pads 40.

The first capacitance-sharing bonding wire CBW1 may electrically connect the first chip voltage pad 211 and the second chip voltage pad 221.

The second capacitance-sharing bonding wire CBW2 may electrically connect the third chip voltage pad 231 and the fourth chip voltage pad 241.

The first voltage bonding wire VBW1, the second voltage bonding wire VBW2, the third voltage bonding wire VBW3, the fourth voltage bonding wire VBW4, the first capacitance-sharing bonding wire CBW1, and the second capacitance-sharing bonding wire CBW2 may be referred to as the voltage bonding wire group VBWG5. In FIG. 17, the voltage bonding wire group VBWG5 is omitted for the convenience of the illustration. While one voltage bonding wire group VBWG5 is shown in FIGS. 18 and 19 for convenience of illustration, the semiconductor package 1003 may include multiple voltage bonding wire groups having the same structure as voltage bonding wire group VBWG2.

The base substrate 100 and the semiconductor chips may be stacked using adhesive layers 71, 72, 73 and 74. The first semiconductor chip 210 may be bonded to a top surface of the base substrate 100 via the first adhesive layer 71, the second semiconductor chip 220 may be bonded to a top surface of the first semiconductor chip 210 via the second adhesive layer 72, the third semiconductor chip 230 may be bonded to a top surface of the second semiconductor chip 220 via the third adhesive layer 73, and the fourth semiconductor chip 240 may be bonded to a top surface of the third semiconductor chip 230 via the fourth adhesive layer 74.

The external terminal 80 may be provided on the lower surface of the base substrate 100. The external terminals 80 may include solder balls or solder pads, and depending on the type of external terminals 80, the semiconductor package 1001 may include a ball grid array (BGA), a fine ball-grid array (FBGA), a land grid array (LGA), or the like.

The molded film 90 may be provided to cover the top surface of the base substrate 100 and the semiconductor chips 210, 220, 230, and 240. The molding film 90 may include an insulating polymeric material such as an epoxy molding compound (EMC).

As shown in FIGS. 17, 18, and 19, the substrate pads 110 may be arranged along a second horizontal direction D2 on at least one of an end portion of the base substrate 100 in the first horizontal direction D1 and an end portion of the base substrate 100 in the opposite direction of the first horizontal direction D1.

The first chip pads 10 may be arranged along the second horizontal direction D2 at an end portion of the first semiconductor chip 210 in the opposite direction of the first horizontal direction D1.

The second chip pads 20 may be arranged along the second horizontal direction D2 at an end portion of the second semiconductor chip 220 in the opposite direction of the first horizontal direction D1.

The third chip pads 30 may be arranged along the second horizontal direction D2 at an end portion of the third semiconductor chip 230 in the opposite direction of the first horizontal direction D1.

The fourth chip pads 40 may be arranged along the second horizontal direction D2 at an end portion of the fourth semiconductor chip 240 in the opposite direction of the first horizontal direction D1.

The second semiconductor chip 220 may be offset in the first horizontal direction D1 relative to the first semiconductor chip 210 such that the first chip pads 10 are exposed toward the vertical direction D3, i.e., such that the second semiconductor chip 220, which is stacked on the first semiconductor chip 210, does not cover the first chip pads 10.

The third semiconductor chip 230 may be overlapped with the first semiconductor chip 210 in a vertical direction D3.

The fourth semiconductor chip 240 may be stacked with the second semiconductor chip 220 in the vertical direction D3.

As shown in FIG. 19, the thickness of the third adhesive layer 73 between the second semiconductor chip 220 and the third semiconductor chip 230 may be larger than the thickness of the second adhesive layer 72 between the first semiconductor chip 210 and the second semiconductor chip 220 and the thickness of the fourth adhesive layer 74 between the third semiconductor chip 230 and the fourth semiconductor chip 240.

By ensuring that the third adhesive layer 73 provides a gap between the second semiconductor chip 220 and the third semiconductor chip 230, the bonding wires VBW1, VBW2, CBW1 may be effectively prevented from being damaged by the third semiconductor chip 230. To this end, the third adhesive layer 73 may be formed to have a large thickness to cover the height of the first capacitance-sharing bonding wire CBW1.

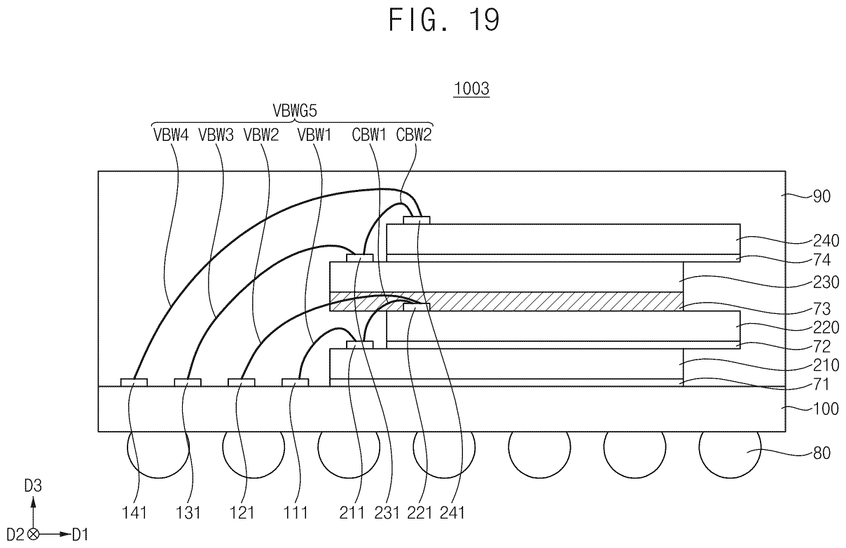

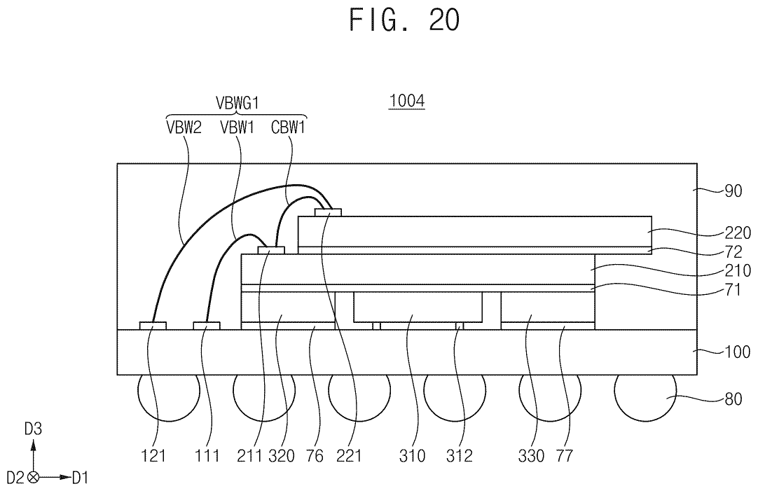

FIG. 20 is a cross-sectional view illustrating a semiconductor package according to example implementations. Hereinafter, description that is redundant with FIGS. 1 through 4 will be omitted.

Referring to FIG. 20, the semiconductor package 1004 may further include a controller chip 310.

The controller chip 310 may be disposed between the first semiconductor chip 210 and the base substrate 100. The controller chip 310 may include logic circuits that control the first semiconductor chip 210 and the second semiconductor chip 220.

The controller chip 310 may be disposed in a center portion of the base substrate 100, and the supporters 320 and 330 may be disposed on either side of the controller chip 310. Accordingly, the stack of the first semiconductor chip 210 and the second semiconductor chip 220 may be balanced by the supporters 320 and 330 on both sides. The supporters 320 and 330 may be bonded to the base substrate 100 by adhesive layers 76, 77. The controller chip 310 may be connected to the base substrate 100 by a conductive inner connector 312. The conductive inner connector may include a conductive member, such as a bump. The first semiconductor chip 210 may be bonded to the controller chip 310 and the supporters 320, 330 by the first adhesive layer 71.

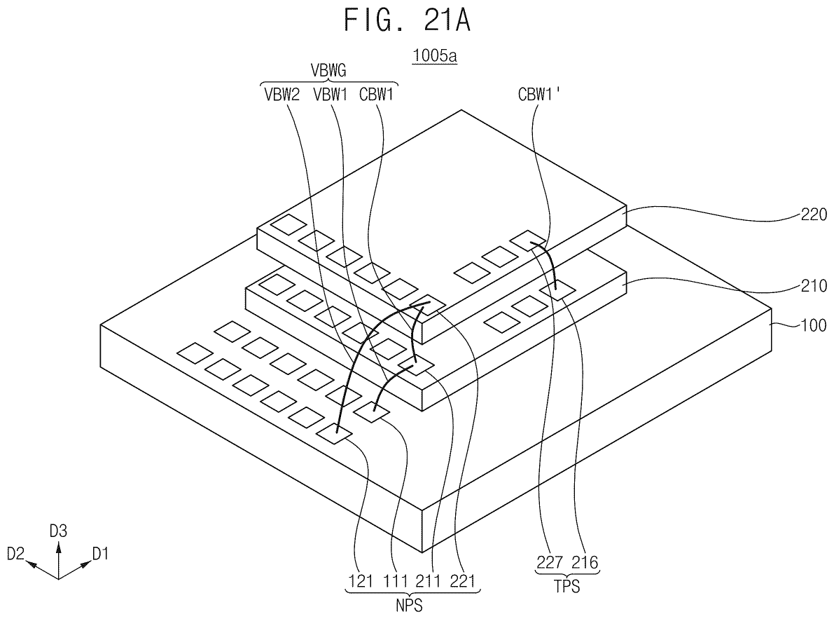

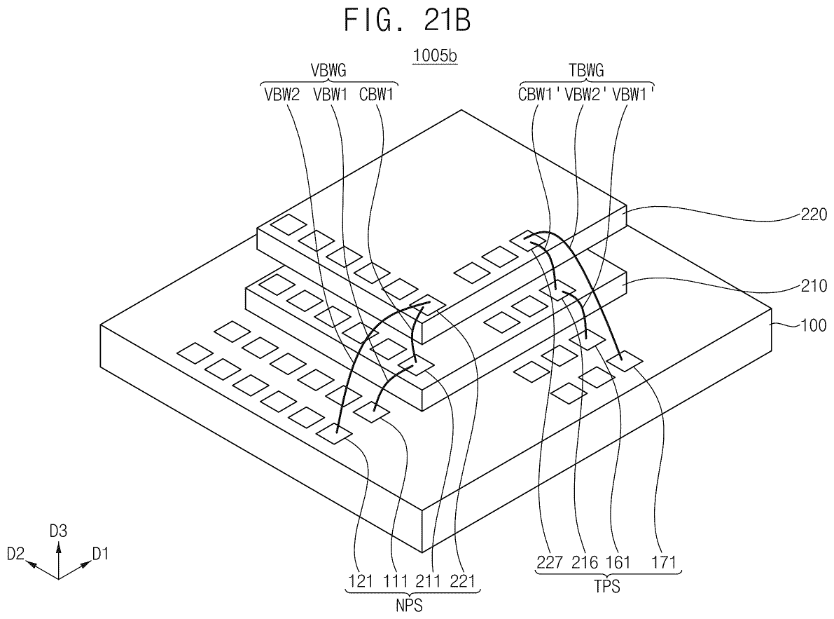

FIGS. 21A and 21B are perspective views illustrating semiconductor packages according to example implementations. Hereinafter, description that is redundant with FIGS. 1 through 4 will be omitted.

Referring to FIG. 21A, a semiconductor package 1005a may further include a test capacitance-sharing bonding wire CBW1′, in addition to the first capacitance-sharing bonding wire CBW1 described above.

The first semiconductor chip 210 may further include a first set of test chip pads, and the second semiconductor chip 220 may further include a second set of test chip pads. The first test chip pads may include a first test chip voltage pad 216 to which a test voltage is applied, and the second test chip pads may include a second test chip voltage pad 227 to which the test voltage is applied.

The first test chip pads may be arranged along the first horizontal direction D1 at an end portion of the first semiconductor chip 210 in the opposite direction of the second horizontal direction D2 of the first semiconductor chip 210, and the second test chip pads may be arranged along the first horizontal direction D1 at an end portion of the second semiconductor chip 220 in the opposite direction of the second horizontal direction D2. The second semiconductor chip 220 may be offset along the second horizontal direction D2 relative to the first semiconductor chip 210 such that the first test chip pads are exposed toward the vertical direction D3.

The normal voltage pads NPS are pads to which a power supply voltage or a ground voltage is applied when the semiconductor package 1005 performs a normal operation that fulfills its intended function. The test voltage pads TPS, on the other hand, are pads to which a test voltage is applied when the first semiconductor chip 210 and the second semiconductor chip 220 are each tested in a discrete state. Here, the discrete state is the state before the semiconductor chips are stacked in a semiconductor package, which may include the state before each semiconductor chip is cut from the wafer or the state after the semiconductor chip is cut from the wafer.

The test capacitance-sharing bonding wire CBW1′ may electrically connect the first test chip voltage pad 216 and the second test chip voltage pad 227.

The first chip voltage pad 211 and the first test chip voltage pad 216 of the first semiconductor chip 210 may be electrically connected to each other via conductive paths formed on the interior of the first semiconductor chip 210. The second chip voltage pad 221 and the second test chip voltage pad 227 of the second semiconductor chip 220 may be electrically connected to each other via conductive paths formed on the interior of the second semiconductor chip 220. In this way, the voltage characteristics of the semiconductor package 1005a during the normal operation may be further improved through capacitance sharing of the test chip voltage pads 216 and 227 after the test is terminated.

Referring to FIG. 21B, the semiconductor package 1005b may further include a test voltage bonding wire group TBWG in addition to the voltage bonding wire group VBWG described above. Hereinafter, description that is redundant to FIG. 21A will be omitted.

The base substrate 100 may further include test substrate pads, the first semiconductor chip 210 may further include first test chip pads, and the second semiconductor chip 220 may further include second test chip pads.

The test voltage bonding wire group TBWG may include a first test voltage bonding wire VBW1′, a second test voltage bonding wire VBW2′, and a test capacitance-sharing bonding wire CBW1′.

The first test voltage bonding wire VBW1′ may electrically connect the first test board voltage pad 161 and the first test chip voltage pad 216 of the first test chip pads to which the test voltage is applied.

The second test voltage bonding wire VBW2′ may electrically connect a second test board voltage pad 171 to which the test voltage is applied, and a second test chip voltage pad 227 of the second test chip pads.

The test capacitance-sharing bonding wire CBW1′ may electrically connect the first test chip voltage pad 216 and the second test chip voltage pad 227.

The first chip voltage pad 211 and the first test chip voltage pad 216 of the first semiconductor chip 210 may be electrically connected to each other via conductive paths formed on the interior of the first semiconductor chip 210. The second chip voltage pad 221 and the second test chip voltage pad 227 of the second semiconductor chip 220 may be electrically connected to each other via conductive paths formed on the interior of the second semiconductor chip 220. In this way, the voltage characteristics of the semiconductor package 1005b during normal operation may be further improved through capacitance sharing of the test chip voltage pads 216, 227 after the test is terminated.

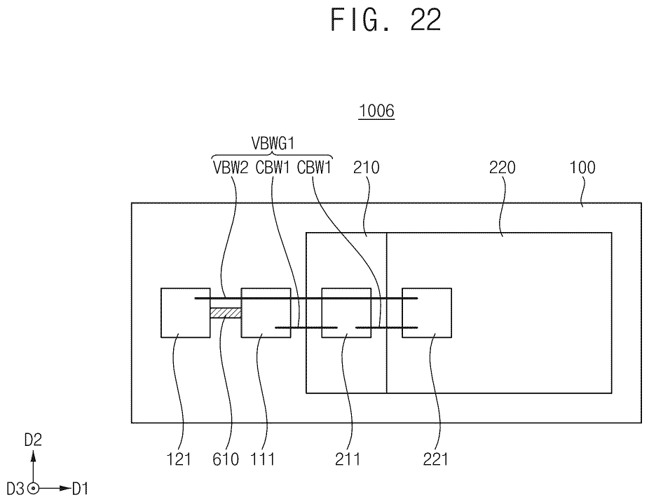

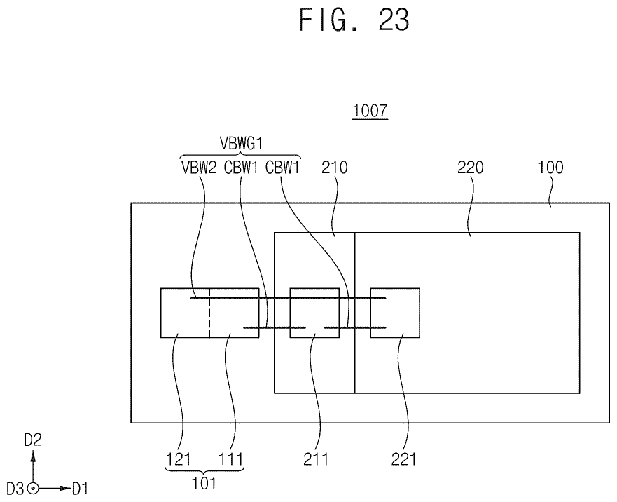

FIGS. 22 and 23 are top views illustrating semiconductor packages according to example implementations. The following description omits redundancies from the foregoing description.

Referring to FIG. 22, the base substrate 100 of the semiconductor package 1006 may further include a conductive path 610 electrically connecting the first substrate voltage pad 111 and the second substrate voltage pad 121.

Referring to FIG. 23, the first substrate voltage pad 111 and the second substrate voltage pad 121 of the semiconductor package 1007 may contact each other to form a single pad 101.

In this way, by implementing capacitance sharing of the substrate voltage pads 111, 121 as well as capacitance sharing of the chip voltage pads 211, 221, the voltage characteristics of the semiconductor package 1006 may be further improved.

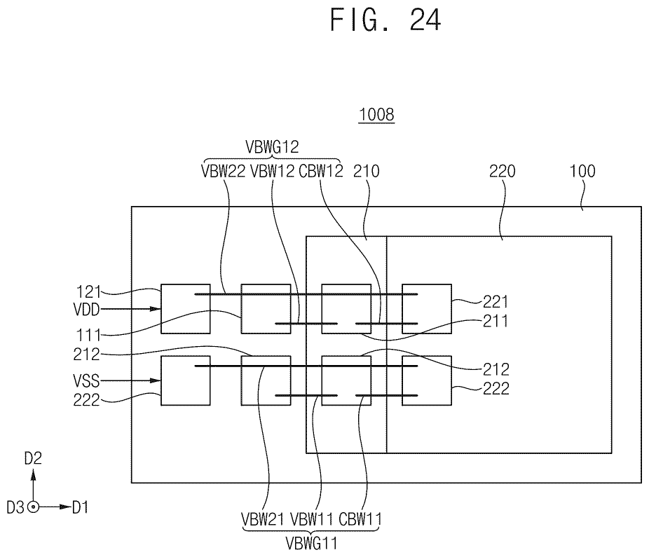

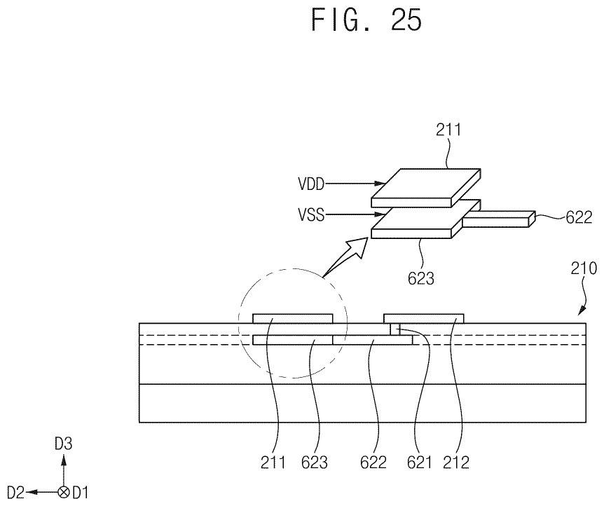

FIG. 24 is a top view illustrating a semiconductor package according to example implementations, and FIG. 25 is a cross-sectional view illustrating a semiconductor chip included in the semiconductor package of FIG. 24. The following description omits redundancies of the foregoing description.

Referring to FIGS. 24 and 25, the first chip pads of the first semiconductor chip 210 may include a first chip power voltage pad 211 that carries a power supply voltage VDD and a first chip ground voltage pad 212 that carries a ground voltage VSS. The first chip power voltage pad 211 and the first chip ground voltage pad 212 are disposed adjacent to each other. Similarly, the second chip pads of the second semiconductor chip 220 may include a second chip power voltage pad 221 that carries the power supply voltage VDD and a second chip ground voltage pad 222 that carries the ground voltage VSS, which are disposed adjacent to each other.

In the upper portion of FIG. 25, an enlarged perspective view of a point source portion is shown. For example, as shown in FIG. 25, the first semiconductor chip 210 may include a dummy pad 623 disposed to face the first chip power voltage pad 211 in the opposite direction of the vertical direction D3 and electrically connected to the first chip ground voltage pad 212. The first chip ground voltage pad 212 and the dummy pad 623 may be connected via a vertical contact 621 and a horizontal conductive pattern 622.

As such, the capacitance of the first chip power voltage pad 211 may be further increased by placing the dummy pad 623 to which the ground voltage VSS is applied.

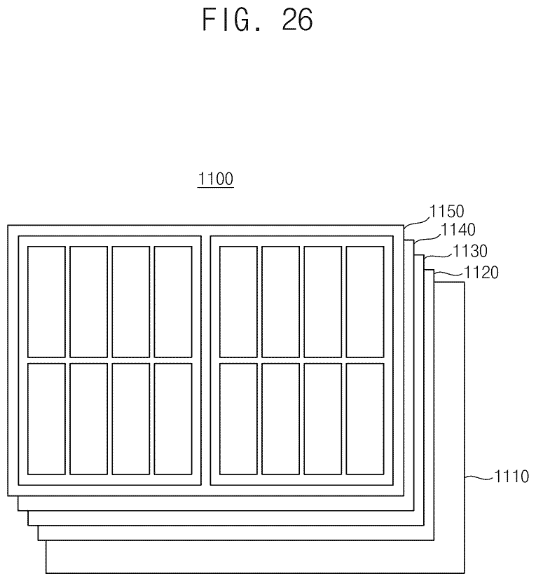

FIG. 26 is a diagram illustrating a stacked memory device according to example implementations.

FIG. 26 illustrates an example high bandwidth memory (HBM) organization. Referring to FIG. 26, a HBM 1100 may have a stack of multiple DRAM semiconductor dies 1120, 1130, 1140, and 1150. The HBM of the stack structure may be optimized by a plurality of independent interfaces, i.e., channels. Each DRAM stack may support up to 8 channels in accordance with HBM standards. FIG. 26 shows an example stack containing 4 DRAM semiconductor dies 1120, 1130, 1140, and 1150, and each DRAM semiconductor die supports two channels CHANNEL0 and CHANNEL1.

Each channel provides access to an independent set of DRAM banks. Requests from one channel may not access data attached to a different channel. Channels are independently clocked, and need not be synchronous.

The HBM 1100 may further include an interface die 1110 or a logic die at bottom of the stack structure to provide signal routing and other functions. Some functions for the DRAM semiconductor dies 1120, 1130, 1140, and 1150 may be implemented in the interface die 1110.

According to example implementations, the HBM 1100 may electrically connect voltage pads of stacked semiconductor dies using capacitance-sharing bonding wires as described above to increase the capacitance of each voltage pad and improve the voltage characteristics of the semiconductor package.

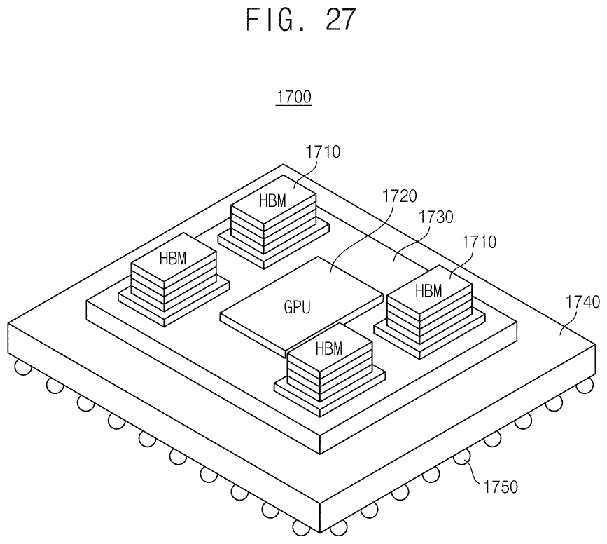

FIG. 27 is a diagram illustrating a semiconductor package including a stacked memory device according to example implementations.

Referring to FIG. 27, a semiconductor package 1700 may include one or more stacked memory devices 1710 and a graphics processing unit (GPU) 1720.

The stacked memory devices 1710 and the GPU 1720 may be mounted on an interposer 1730, and the interposer on which the stacked memory device 1710 and the GPU 1720 are mounted may be mounted on a package substrate 1740. The package substrate 1740 is mounted on solder balls 1750. The GPU 1720 may perform the same operation as the memory controller as described above or may include the memory controller. The GPU 1720 may store data, which is generated or used in graphic processing in the stacked memory devices 1710.

The stacked memory device 1710 may be implemented in various forms, and the stacked memory device 1710 may be a memory device in a high bandwidth memory (HBM) form in which a plurality of layers are stacked. The stacked memory device 1710 may include a buffer die and a plurality of memory dies.

According to example implementations, the stacked memory device 1710 may electrically connect voltage pads of stacked semiconductor dies using capacitance-sharing bonding wires as described above to increase the capacitance of each voltage pad and improve the voltage characteristics of the semiconductor package.

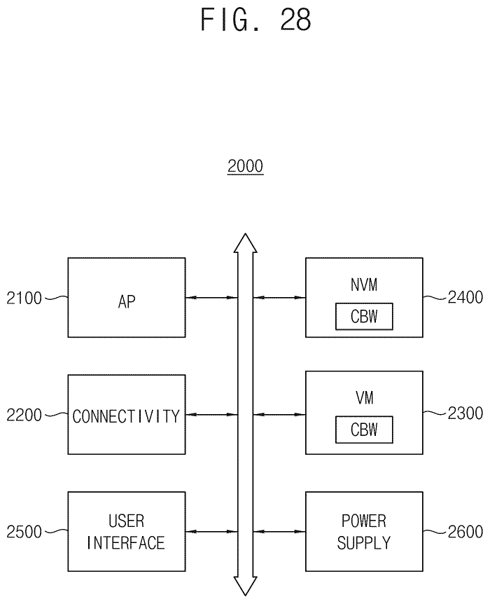

FIG. 28 is a block diagram illustrating a mobile system according to example implementations.

Referring to FIG. 36, a mobile system 2000 may include an application processor (AP) 2100, a connectivity unit 2200, a volatile memory device (VM) 2300, a nonvolatile memory device (NVM) 2400, a user interface 2500, and a power supply 2600. In some implementations, the mobile system 2000 may be, for example, a mobile phone, a smart phone, a personal digital assistant (PDA), a portable multimedia player (PMP), a digital camera, a music player, a portable game console, a navigation system, or another type of electronic device.

The application processor 2100 may execute applications, e.g., a web browser, a game application, a video player, and so on. The connectivity unit 2200 may perform wired or wireless communication with an external device. The volatile memory device 2300 may store data processed by the application processor 2100 or may operate as a working memory. The nonvolatile memory device 2400 may store a boot image for booting the mobile system 2000. The user interface 2500 may include at least one input device, such as a keypad, a touch screen, etc., and at least one output device, such as a speaker, a display device, etc. The power supply 2600 may supply a power supply voltage to the mobile system 2000.

According to example implementations, the semiconductor memory device 2300 and/or the non-volatile semiconductor memory device 2400 may electrically connect voltage pads of stacked semiconductor die using capacitance sharing bonding wires CBW as described above to increase the capacitance of each voltage pad and improve the voltage characteristics of the semiconductor package.

As described above, the semiconductor package according to example implementations may improve the voltage characteristics of the semiconductor package by electrically connecting the voltage pads of stacked semiconductor chips using capacitance-sharing bonding wires to increase the capacitance of each voltage pad.

Implementations described herein may be applied to a semiconductor package and systems including a semiconductor package. For example, implementations may be applied to systems such as a memory card, a solid state drive (SSD), an embedded multimedia card (eMMC), a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive device, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in the example implementations without materially departing from the present disclosure.

What is claimed is:

1. A semiconductor package comprising:
a base substrate including substrate pads;
a first semiconductor chip stacked on the base substrate in a vertical direction and including first chip pads;
a second semiconductor chip stacked on the first semiconductor chip in the vertical direction and including second chip pads:
a first voltage bonding wire electrically connecting a first substrate voltage pad of the substrate pads and a first chip voltage pad of the first chip pads, wherein a power supply voltage or a ground voltage is configured to be applied to the first substrate voltage pad;
a second voltage bonding wire electrically connecting a second substrate voltage pad of the substrate pads and a second chip voltage pad of the second chip pads, wherein the power supply voltage or the ground voltage is configured to be applied to the second substrate voltage pad; and
a first capacitance-sharing bonding wire electrically connecting the first chip voltage pad and the second chip voltage pad.

2. The semiconductor package of claim 1, further comprising:
a first signal bonding wire electrically connecting a first substrate input-output pad of the substrate pads and a first chip input-output pad of the first chip pads; and
a second signal bonding wire electrically connecting a second substrate input-output pad of the substrate pads and a second chip input-output pad of the second chip pads,
wherein the first chip input-output pad and the second chip input-output pad are electrically isolated from each other.

3. The semiconductor package of claim 2, wherein a respective capacitance of the first chip voltage pad and the second chip voltage pad is larger than a respective capacitance of the first chip input-output pad and the second chip input-output pad.

4. The semiconductor package of claim 1, wherein the substrate pads are arranged along a second horizontal direction on at least one of an end portion of the base substrate in a first horizontal direction or an end portion of the base substrate in an opposite direction of the first horizontal direction,
wherein the first chip pads are arranged along the second horizontal direction at an end portion of the first semiconductor chip in the opposite direction of the first horizontal direction,
wherein the second chip pads are arranged along the second horizontal direction at an end portion of the second semiconductor chip in the opposite direction of the first horizontal direction, and
wherein the second semiconductor chip is offset along the first horizontal direction from the first semiconductor chip such that the first chip pads are exposed toward the vertical direction.

5. The semiconductor package of claim 4, further comprising:
a third semiconductor chip stacked on the second semiconductor chip in the vertical direction and including third chip pads:
a fourth semiconductor chip stacked on the third semiconductor chip in the vertical direction and including fourth chip pads:
a third voltage bonding wire electrically connecting a third substrate voltage pad of the substrate pads and a third chip voltage pad of the third chip pads, wherein the power supply voltage or the ground voltage is configured to be applied to the third substrate voltage pad;
a fourth voltage bonding wire electrically connecting a fourth substrate voltage pad of the substrate pads and a fourth chip voltage pad of the fourth chip pads, wherein the power supply voltage or the ground voltage is configured to be applied to the fourth substrate voltage pad; and
a second capacitance-sharing bonding wire electrically connecting the third chip voltage pad and the fourth chip voltage pad.

6. The semiconductor package of claim 5, wherein the third chip pads are arranged along the second horizontal direction at an end portion of the third semiconductor chip in the opposite direction of the first horizontal direction,
wherein the fourth chip pads are arranged along the second horizontal direction at an end portion of the fourth semiconductor chip in the opposite direction of the first horizontal direction,
wherein the third semiconductor chip is offset in the first horizontal direction from the second semiconductor chip such that the second chip pads are exposed toward the vertical direction, and
wherein the fourth semiconductor chip is offset in the first horizontal direction from the third semiconductor chip such that the third chip pads are exposed toward the vertical direction.

7. The semiconductor package of claim 6, further comprising:
a third capacitance-sharing bonding wire electrically connecting the second chip voltage pad and the third chip voltage pad.

8. The semiconductor package of claim 5, wherein the third chip pads are arranged along the second horizontal direction at an end portion of the third semiconductor chip in the first horizontal direction,
wherein the fourth chip pads are arranged along the second horizontal direction at an end portion of the fourth semiconductor chip in the first horizontal direction,
wherein the third semiconductor chip is offset in the first horizontal direction from the second semiconductor chip such that the second chip pads are exposed toward the vertical direction, and
wherein the fourth semiconductor chip is offset in the opposite direction of the first horizontal direction from the third semiconductor chip such that the third chip pads are exposed toward the vertical direction.

9. The semiconductor package of claim 5, wherein the third chip pads are arranged along the second horizontal direction at an end portion of the third semiconductor chip in the opposite direction of the first horizontal direction,
wherein the fourth chip pads are arranged along the second horizontal direction at an end portion of the fourth semiconductor chip in the opposite direction of the first horizontal direction,
wherein the third semiconductor chip overlaps the first semiconductor chip in the vertical direction, and
wherein the fourth semiconductor chip overlaps the second semiconductor chip in the vertical direction.

10. The semiconductor package of claim 9, wherein a thickness of an adhesive layer between the second semiconductor chip and the third semiconductor chip is greater than a thickness of an adhesive layer between the first semiconductor chip and the second semiconductor chip and a thickness of an adhesive layer between the third semiconductor chip and the fourth semiconductor chip.

11. The semiconductor package of claim 1, further comprising:
a controller chip that is arranged between the first semiconductor chip and the base substrate, wherein a logic circuit is integrated in the controller chip and is configured to control the first semiconductor chip and the second semiconductor chip.

12. The semiconductor package of claim 1, wherein the first semiconductor chip further includes first test chip pads, and
wherein the second semiconductor chip further includes second test chip pads.

13. The semiconductor package of claim 12, further comprising:
a test capacitance-sharing bonding wire electrically connecting a first test chip voltage pad of the first test chip pads and a second test chip voltage pad of the second test chip pads.

14. The semiconductor package of claim 12, wherein the first test chip pads are arranged along a first horizontal direction at an end portion of the first semiconductor chip in an opposite direction of a second horizontal direction,
wherein the second test chip pads are arranged along the first horizontal direction at an end portion of the second semiconductor chip in the opposite direction of the second horizontal direction, and
wherein the second semiconductor chip is offset in the second horizontal direction from the first semiconductor chip such that the first test chip pads are exposed toward the vertical direction.

15. The semiconductor package of claim 1, wherein the base substrate further includes a conductive path electrically connecting the first substrate voltage pad and the second substrate voltage pad.

16. The semiconductor package of claim 1, wherein the first substrate voltage pad and the second substrate voltage pad contact each other to form one pad.

17. The semiconductor package of claim 1, wherein the first chip pads include:
a first chip power voltage pad configured to transfer the power supply voltage, and
a first chip ground voltage pad configured to transfer the ground voltage, wherein the first chip power voltage pad and the first chip ground voltage pad are adjacent to each other, and
wherein the first semiconductor chip includes a dummy pad that is arranged to face the first chip power voltage pad in an opposite direction of the vertical direction and is electrically connected to the first chip ground voltage pad.

18. The semiconductor package of claim 1, wherein at least one of the first semiconductor chip or the second semiconductor chip is a memory semiconductor die including DRAM cells.

19. A semiconductor package comprising:
a base substrate including substrate voltage pads;
a plurality of semiconductor chips that are sequentially stacked on the base substrate in a vertical direction and each including chip pads;
voltage bonding wires electrically connecting each substrate voltage pad of the substrate voltage pads and each chip voltage pad of the chip pads, wherein a power supply voltage or a ground voltage is configured to be applied to a first substrate voltage pad of the substrate voltage pads; and
capacitance-sharing bonding wires each electrically connecting chip voltage pads included in different semiconductor chips among the plurality of semiconductor chips.

20. A semiconductor package comprising:
a base substrate including substrate pads;
a first memory semiconductor chip stacked on the base substrate in a vertical direction and including first chip pads;
a second memory semiconductor chip stacked on the first memory semiconductor chip in the vertical direction and including second chip pads:
a first voltage bonding wire electrically connecting a first substrate voltage pad of the substrate pads and a first chip voltage pad of the first chip pads, wherein a power supply voltage is configured to be applied to the first substrate voltage pad;
a second voltage bonding wire electrically connecting a second substrate voltage pad of the substrate pads and a second chip voltage pad of the second chip pads, wherein the power supply voltage is configured to be applied to the second substrate voltage pad; and
a capacitance-sharing bonding wire electrically connecting the first chip voltage pad and the second chip voltage pad,
wherein one of the first memory semiconductor chip or the second memory semiconductor chip is configured to be selectively activated based on chip selection signals.
